(19) United States
(12) Patent Application Publication
(10) Pub. No.: US 2025/0220958 A1
(43) Pub. Date: Jul. 3, 2025

(54) SOURCE/DRAIN CONTACT TRENCH WITH DIELECTRIC LINER ON CONTACT METAL

(71) Applicant: Intel Corporation, Santa Clara, CA (US)

(72) Inventors: Gilbert Dewey, Beaverton, OR (US); Nancy Zelick, Portland, OR (US); Ilya V. Karpov, Portland, OR (US); Christopher Jezewski, Portland, OR (US); Siddharth Chouksey, Portland, OR (US); Thoe Kathy Michaelos, Portland, OR (US); Nazila Haratipour, Portland, OR (US); Arnab Sen Gupta, Hillsboro, OR (US); I-Cheng Tung, Hillsboro, OR (US)

(21) Appl. No.: 18/397,976

(22) Filed: Dec. 27, 2023

(51) Int. Cl. H01L 29/417; H01L 21/8238; H01L 27/092; H01L 29/06; H01L 29/423; H01L 29/66; H01L 29/775; H01L 29/78; H01L 29/786

(52) U.S. Cl. CPC H10D 30/6729; H10D 30/014; H10D 30/024; H10D 30/43; H10D 30/6211; H10D 30/6219; H10D 30/6735; H10D 30/6757; H10D 62/121; H10D 84/017; H10D 84/0193; H10D 84/038; H10D 84/853

(57) ABSTRACT

An integrated circuit device comprising at least one first layer at a bottom of a trench, the at least one layer connecting to a source/drain region of a transistor, the at least one layer comprising metal; a second layer on the at least one first layer, the second layer comprising metal; and a third layer on the at least one first layer and within the trench, the third layer comprising a dielectric material.

### BACKGROUND

In the context of field-effect transistors (FETs), a source-drain contact trench may refer to a trench that includes a contact metal that connects to a source region or a drain region structure and to a fill metal that electrically couples the source region or drain region to a line that may electrically couple to other terminals of the same transistor or other transistors or other circuitry.

### BRIEF DESCRIPTION OF THE DRAWINGS

FIG. 1 illustrates a cross section of an example nanoribbon gate-all-around field effect transistor (GAAFET) architecture with a dielectric liner on top of a contact metal structure within a source/drain contact trench.

FIG. 2 illustrates an example transistor architecture with dual dielectric liners in a source/drain contact trench.

FIGS. 3A-3B illustrate a flow for forming a transistor architecture with a dielectric liner on a contact metal structure.

FIGS. 4A-4C illustrate a flow for forming a transistor architecture with dual dielectric liners in a source/drain contact trench.

FIG. 5 provides a schematic illustration of a cross-sectional view of an example integrated circuit device, in accordance with any of the embodiments disclosed herein.

FIG. 6 is a top view of a wafer and dies that may be included in a microelectronic assembly, in accordance with any of the embodiments disclosed herein.

FIG. 7 is a cross-sectional side view of an integrated circuit device that may be included in a microelectronic assembly, in accordance with any of the embodiments disclosed herein.

FIGS. 8A-8D are perspective views of example planar, FinFET, gate-all-around, and stacked gate-all-around transistors.

FIG. 9 is a cross-sectional side view of an integrated circuit device assembly that may include a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

Major components of a transistor may include a gate, a channel, a source, and a drain. Herein the term source/drain may refer to either a source or drain of a transistor. As the pitch between adjacent transistors scales downwards, the gate-to-contact capacitance (e.g., a parasitic capacitance between a gate line that connects to transistor gates and a substantially parallel source/drain line that connects to transistor source/drains) is susceptible to increasing and the contact area of the interface between a contact metal and the source/drain material (e.g., doped epitaxial silicon or other suitable material) is susceptible to decreasing (thus increasing the contact resistance). Both of these factors may decrease the performance of the transistors.

As an example, during formation of a trench for the source/drain contacts (e.g., including at least one contact metal and a fill metal), various etches and cleans are performed. These processing steps can affect the width of the trench. If the trench becomes too wide, then the source/drain contacts may touch the gate, resulting in a short circuit. A large width for a source/drain contact trench can also have a negative effect on the capacitance between a gate line and a source/drain line as the metals are placed closer together.

A trench contact liner (e.g., comprising silicon nitride) that protects against deleterious etching effects occurring in the source/drain contact trench may be used to improve yield (e.g., by protecting against shorting between the source/drain contact and the gate), but trench contact liners with high dielectric constants (e.g., k=˜8) may result in a higher than desired capacitance between the source/drain contact and the gate, especially if the source/drain contact and the gate are too close together.

Various embodiments of the present disclosure provide transistors in which a dielectric liner is placed inside of a source/drain contact trench and on top of a contact metal structure comprising at least one contact metal layer. Some embodiments include an additional dielectric liner on the outside of the dielectric liner that is on the contact metal structure, where the additional dielectric liner may extend downwards on the sidewalls of the trench and along the sides of the contact metal structure. The additional dielectric liner may have a higher dielectric constant than the inner dielectric liner. In some examples, the at least one contact metal of the contact metal structure may comprise a base contact metal that is in contact with the source/drain region and a cap contact metal that is on top of the base contact metal. The dielectric liner may then be formed on top of the cap contact metal. In various embodiments, the cap contact metal may comprise a refractory metal.

Various embodiments may lead to one or more advantages, such as a larger contact area (and lower contact resistance), improved gate-to-contact capacitance (as the source/drain fill metal is further from the gate contact), faster transistors, and higher yield (e.g., due to increased thickness of a dielectric liner between a fill metal and a gate).

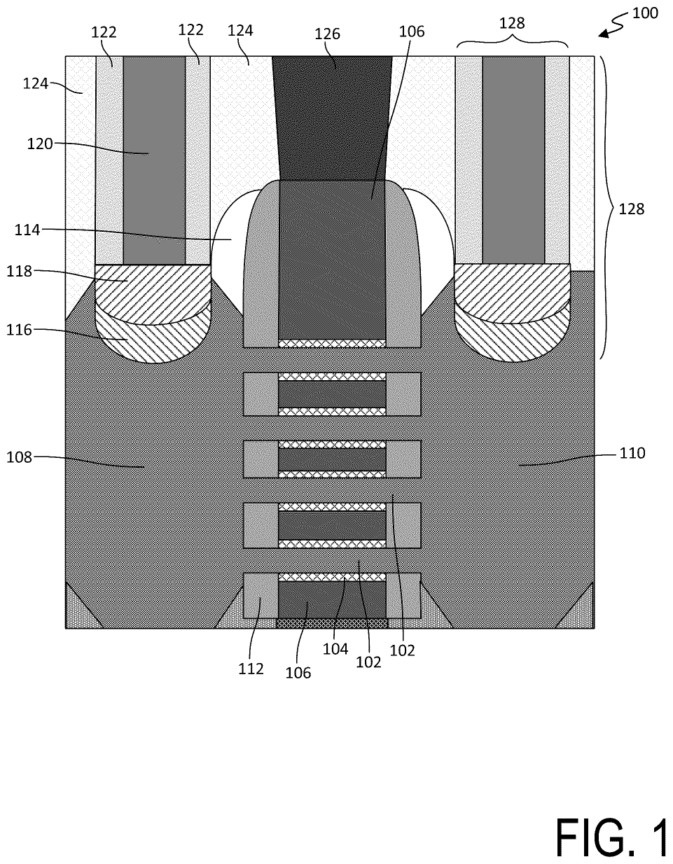

FIG. 1 illustrates a cross section view of an example gate-all-around field effect transistor (GAAFET) architecture 100. The architecture 100 depicted includes a transistor with nanoribbons 102 (e.g., silicon nanoribbons) that are each surrounded by a dielectric material 104 (e.g., a high k dielectric) and a gate metal 106. In various embodiments, the stack of nanoribbons 102 may be epitaxially grown on a substrate (e.g., a silicon substrate). The nanoribbons 102 couple a source region 108 of a transistor to a drain region 110 and may function as the channel of the transistor.

In a particular embodiment, source region 108 and drain region 110 may comprise epitaxial silicon doped with impurities to generate excess charge carriers, while the nanoribbons 102 may comprise undoped silicon. Although not shown, in some embodiments, a source/drain region of a transistor may include a nucleation layer that is connected to the channel material and a main layer that is connected to the nucleation layer. The main layer may also be connected to a contact metal structure comprising at least one metal contact (e.g., 116, 118) for the source/drain. In various embodiments, the nucleation layer is epitaxial and is in between and/or in contact with nanoribbons 102 and the main layer. In various embodiments, the nucleation layer buffers the main layer from directly contacting the channel material (e.g., nanoribbons 102).

In order to isolate various components (e.g., to prevent shorting between the drain/source regions and the gate metal 106) and reduce parasitic capacitance, one or more spacers 112, 114 may be formed (e.g., in between portions of gate metal 106 and the source/drain). The spacers 112, 114 may comprise, e.g., silicon nitride, silicon nitride with oxygen and/or carbon doping, silicon oxide, silicon carbide, silicon oxynitride, or other suitable dielectric material.

A contact metal structure comprising at least one contact metal 116, 118 may be recessed within a source/drain trench 128 and may contact the source/drain region 108 or 110. In various embodiments, at least a portion of one or more of the contact metals may be below the highest point of the source/drain region. The contact metal structure comprising at least one contact metal 116, 118 is also connected to a fill metal 120 which interfaces with the at least one contact metal at the top of the at least one contact metal.

In this embodiment, the contact metal structure includes a base contact metal 116 and a cap contact metal 118 that is on the base contact metal 116. In various examples, the base contact metal may provide a good adhesion layer, form a nice silicide with the drain/source material, and/or have a low resistance. In various examples, the base contact metal may comprise a metal or alloy comprising any one or more of titanium, nickel, molybdenum, titanium aluminum, erbium, gadolinium, aluminum, platinum, gold, scandium, zirconium, tungsten, niobium, tantalum, and cobalt.

In some embodiments, a cap contact metal 118 may be formed on the base contact metal 116. In some instances, the cap contact metal 118 may be formed in situ (e.g., formed without the base contact metal 116 being exposed to air to avoid oxidation between the base contact metal 116 and cap contact metal 118) The cap contact metal 118 may also be recessed within the trench. In various examples, the cap contact metal 118 may be low resistance, provide a good oxygen barrier, have a high work function value resulting in low reactivity, and/or be easily etched.

In various embodiments, the metal cap comprises a refractory metal (or alloy comprising a refractory metal) such as tungsten, molybdenum, niobium, tantalum, rhenium, titanium, vanadium, chromium, zirconium, hafnium, ruthenium, rhodium, osmium, or iridium. In some embodiments, the metal cap may comprise cobalt. In yet other embodiments, the metal cap comprises a metal nitride (e.g., titanium nitride) or a metal carbide (e.g., titanium carbide, titanium aluminum carbide) (e.g., that provides a good diffusion barrier and is less prone to oxidation).

The architecture 100 also includes a dielectric liner 122 that lines at least a portion of the sidewalls of the contact trench. The bottom of the dielectric liner 122 is on top of the contact metal structure comprising at least one contact metal 116, 118. In the embodiment shown, the dielectric liner 122 is on the cap contact metal 118. In at least some embodiments, the dielectric liner 122 does not contact the source/drain. The dielectric liner 122 may comprise any suitable combination of silicon, oxygen, carbon, and/or nitrogen. For example, the dielectric liner 122 may comprise one or more of silicon nitride, silicon oxynitride, silicon carbide, silicon oxycarbide, and silicon oxide.

The architecture also includes a fill metal 120 that is in contact with the at least one contact metal and thus electrically coupled to the source/drain region. In the depicted embodiment, the fill metal 120 is on the cap contact metal 118. The fill metal 120 is bounded on its outer perimeter by the dielectric liner 122. The fill metal 120 typically has a lower resistance than the at least one contact metal of the contact metal structure. In some embodiments, the fill metal 120 may comprise a low resistance and non-reactive metal or alloy. In various examples, the fill metal may include cobalt, molybdenum, tungsten, ruthenium, copper, or other suitable metal or alloy. The fill metal may connect to a source/drain line and thus may electrically couple the source/drain region to the source/drain line.

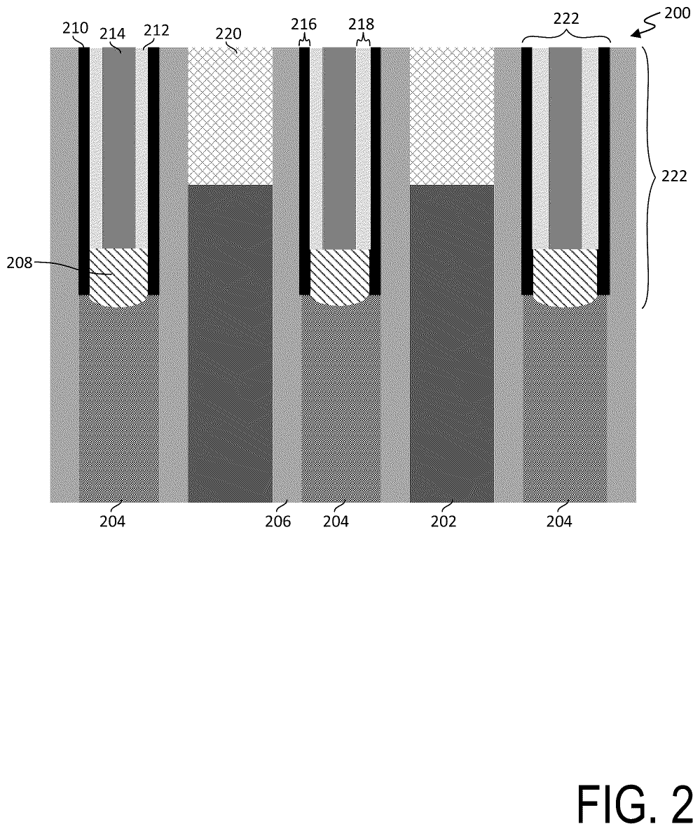

The architecture 100 also includes an interlayer dielectric (ILD) 124 in contact with the outside of the dielectric liner 122. When a contact trench is formed a portion of the ILD 124 may be removed (e.g., by an etch) to form the trench. The etch may stop proximate the source/drain region (e.g., either on top of the source/drain region or it may remove a small portion of the source/drain region, thus forming a small indentation in the source/drain region). The ILD 124 may surround the dielectric liner 122 and may be in between dielectric liner 122 and the gate metal 106 and/or a via 126 connected to the gate metal 106. The ILD 124 may comprise any suitable dielectric material, such as silicon dioxide or silicon oxycarbide. ILD may also be referred to as a spacer in some embodiments (e.g., the spacers shown in FIGS. 2-4 could include a portion of an ILD layer).

In various embodiments, the contact trench 128 and the materials therein may extend laterally (e.g., in a direction through the page) and the same trench (and at least some of the materials therein such as the liners and metal fill) may span across a plurality of source/drains of multiple transistors (at least until cuts are made to facilitate the formation of various circuits). Thus, at least for a portion of the trench, the trench may have two sidewalls and the materials within the trench may be contained within these sidewalls.

In various embodiments, the architecture 100 may include an additional dielectric liner in the contact trench (on the outside of the dielectric liner 122), similar to that described in connection with FIG. 2.

FIG. 2 illustrates an example transistor architecture 200 with dual dielectric liners 210, 212 in a source/drain contact trench. Architecture 200 includes gate regions 202, which are separated from source/drain regions 204 by spacers 206. A spacer 206 may include one or more dielectric materials separating a gate region and/or a contact to a gate region from a source/drain region and/or source/drain contacts. The architecture 200 may also include dielectric caps 220 (e.g., comprising silicon nitride) on the gate regions 202 to protect against shorting of a gate line to a source/drain line and to reduce capacitance. If a gate region is to be connected to the corresponding gate line, a via may replace at least a portion of the dielectric cap above the gate region.

Architecture 200 also includes contact metal structure 208 which is recessed within the contact trench 222. The contact metal structure 208 may have any suitable characteristics of the contact metal structure described in connection with FIG. 1. In one embodiment, the contact metal structure 208 includes a titanium layer on the bottom of the trench and in contact with the source/drain 204 and a cap of a molybdenum layer on top of the titanium. The capping may prevent titanium oxidation and preserve low contact resistance while the recessing of the contact metal structure 208 within the contact trench may enable a second dielectric liner (e.g., inner liner 212) to be deposited within the contact trench without unduly increasing the contact resistance.

Architecture 200 includes dual dielectric liners: an outer liner 210 and an inner liner 212. The outside liner 210 may provide characteristics that improve yield by protecting against excessive widening of the contact trench (e.g., the outer liner 210 may be more robust to certain etches than the inner liner 212). The inner liner 212 may help reduce the parasitic capacitance between a gate line and a source/drain line (e.g., in some embodiments, the inner liner 212 may comprise a dielectric material with a lower k value than the dielectric material of the outer liner 210).

The outer liner 210 may be deposited before the contact metal structure 208 is deposited and thus at least a portion of the outer liner may extend down the sidewalls of the trench to the material (e.g., epitaxial silicon) of the source/drain 204. However, the inner liner 212 may be deposited after the contact metal structure 208 is deposited and thus may be on the contact metal structure 208 and is not in contact with the material of the source/drain 204.

The outside of the inner liner 212 is in contact with the inside of the outer liner 210. In various embodiments, the thickness 216 of the outer liner 210 may be greater than the thickness 218 of the inner liner 212, the thickness 216 of the outer liner 210 may be less than the thickness 218 of the inner liner 212, or the two thicknesses may be substantially equal.

In various embodiments, an outer liner 210 and inner liner 212 may comprise two or more of silicon, oxygen, carbon, and/or nitrogen. For example, the liners may comprise one or more of silicon nitride, silicon oxynitride, silicon carbide, silicon oxycarbide, and silicon oxide. As mentioned above, the inner liner 212 may be a dielectric material with a k value that is lower than the k value of the dielectric material of the outer liner 210 (e.g., to provide reduced capacitive coupling). In various embodiments, the concentration (e.g., atomic percentage) of nitrogen is higher in the outer liner 210 than in the inner liner 212. In certain examples, the concentration (e.g., atomic percentage) of oxygen is lower in the outer liner 210 than in the inner liner 212. In some embodiments, the outer liner 210 comprises predominantly silicon nitride. In various embodiments, the inner liner 212 has a higher concentration of silicon oxide than the outer liner 210.

The architecture 200 also includes a fill metal 214 that is in contact with the at least contact metal structure 208 and thus electrically coupled to the source/drain region 204. The fill metal 214 is bounded on its outer perimeter by the inner liner 212.

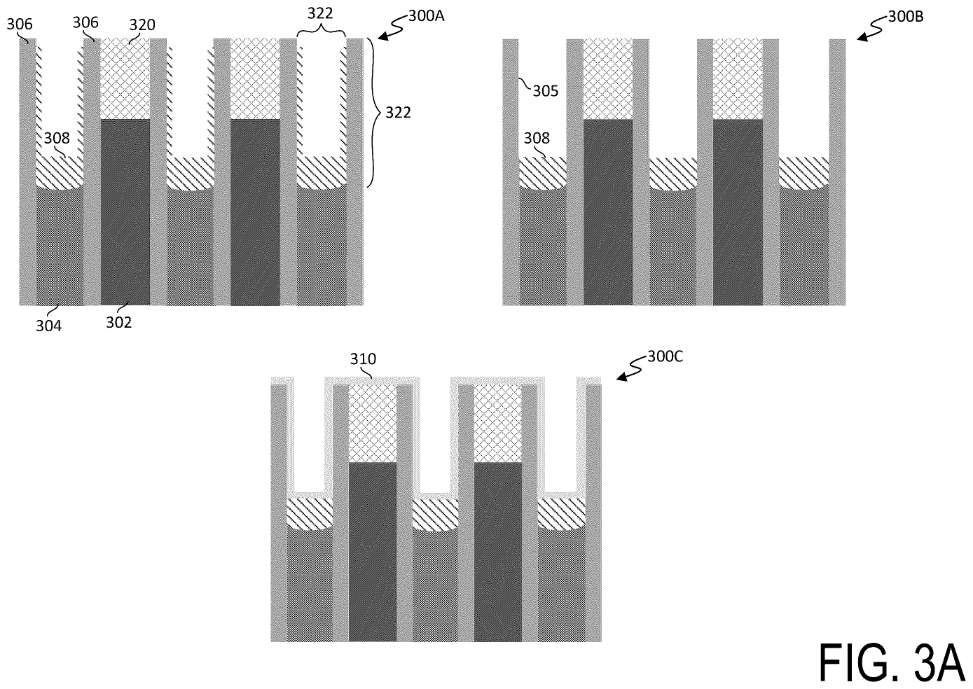

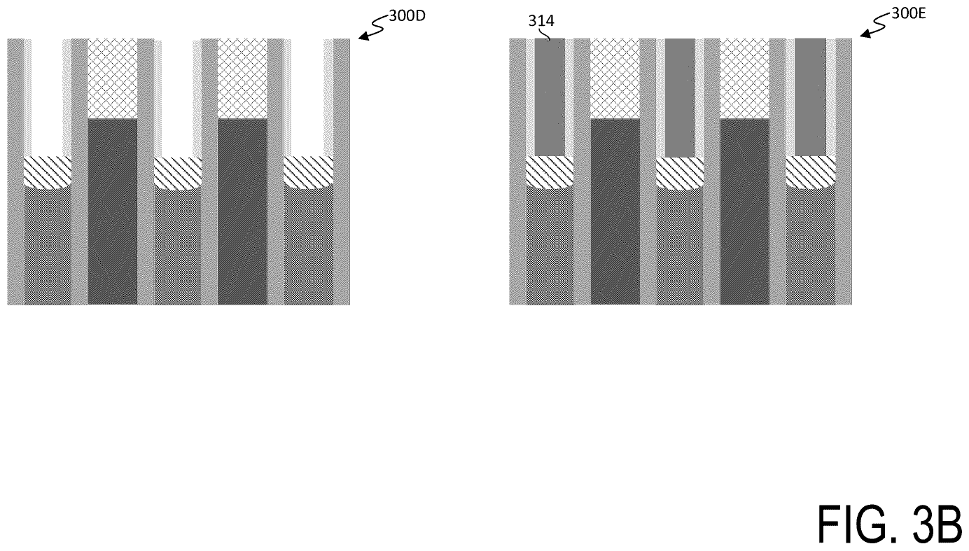

FIGS. 3A-3B illustrate a flow for forming a transistor architecture with a dielectric liner on a contact metal structure. The flow illustrates stages 300A-300E. The flow begins at stage 300A. At stage 300A, the architecture includes gate regions 302, source/drain regions 304, spacers 306, and dielectric caps 320. Drain/source contact trenches 322 have already been formed and at least one contact metal layer 308 has been deposited within the trenches. In some embodiments, a first contact metal layer may first be deposited, wherein a portion of the first contact metal layer settles at the bottom of the trench and other portions of the first contact metal layer are formed on the sidewalls of the trench. A second contact metal layer (e.g., comprising a cap contact metal) is then deposited on the first contact metal layer (with some of the second contact metal layer contacting the first contact metal layer along the sidewalls of the trench and some of the second contact metal layer contacting the first contact metal layer at the bottom of the trench). As shown the height of the at least one contact metal at the bottom of the trench is greater than the width of the at least one contact metal along the sidewalls of the trench. In various embodiments, any suitable deposition techniques (e.g., physical vapor deposition) may be used to form the at least one contact metal layer 308.

At stage 300B, portions of the at least one contact metal layer 308 that were along at least a portion of the sidewalls 305 of the trench 322 are removed (e.g., as leaving them there would have a significantly negative effect on the capacitance). The removal may be accomplished in any suitable manner, e.g., by applying an etch material.

At stage 300C, a dielectric liner layer 310 is formed on the spacers 306, trench sidewalls 305, at least one contact metal layer 308, and dielectric cap 320. In some embodiments, the dielectric liner layer 310 may have a relatively uniform thickness.

At stage 300D, unwanted portions of the dielectric liner layer 310 are removed (e.g., through etching). For example, the portions of layer 310 over the spacers 306 and dielectric caps may be removed. A portion of the layer 310 that is on the at least one contact metal layer 308 may also be removed (e.g., using a directional etch) to expose the at least one contact metal layer 308.

At stage 300E, a fill metal layer 314 (e.g., tungsten, molybdenum, cobalt, etc.) is then deposited on the at least one contact metal layer 308 within a border defined by the dielectric liner layer 310.

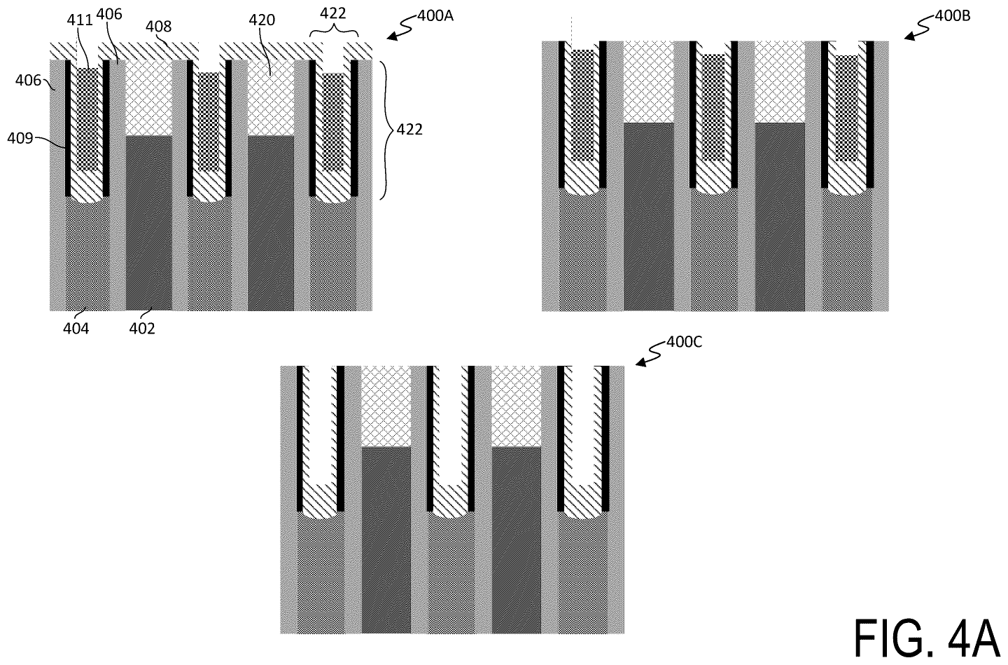

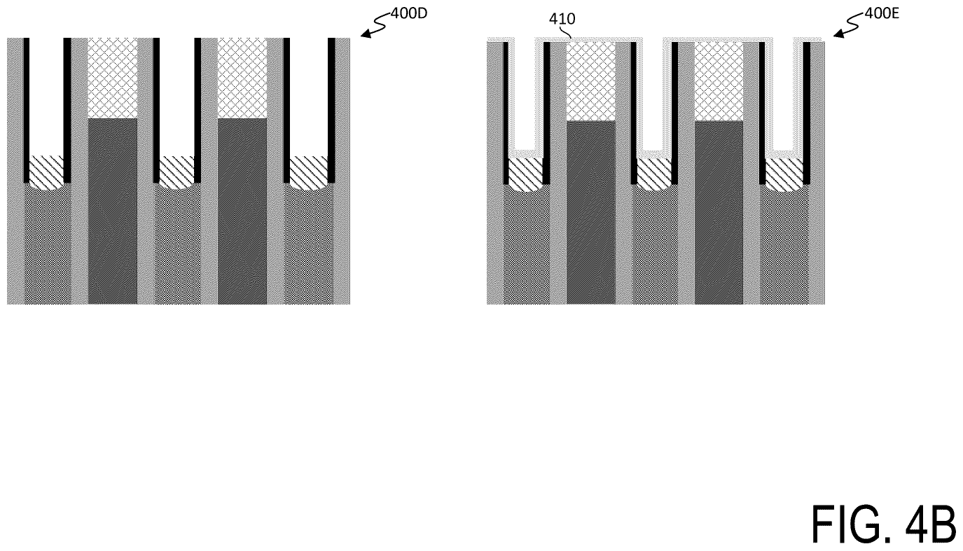

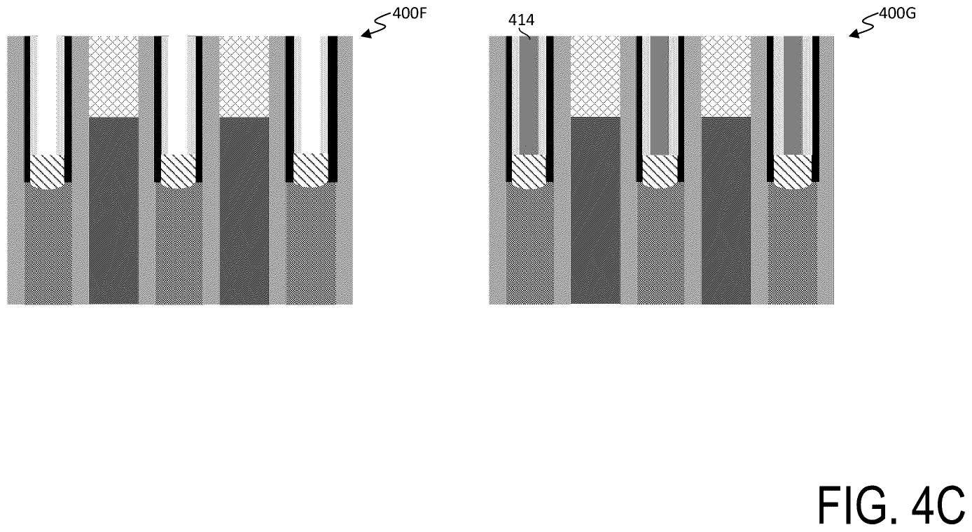

FIGS. 4A-4C illustrate a flow for forming a transistor architecture with dual dielectric liners in a source/drain contact trench.

The flow illustrates stages 400A-400G. The flow begins at stage 400A. At stage 400A, the architecture includes gate regions 402, source/drain regions 404, spacers 406, and dielectric caps 420. Drain/source contact trenches 422 have already been formed. After the trenches 422 are formed, a first dielectric liner layer 409 is deposited on the sidewalls of the trench (in some embodiments, a portion of the layer 409 may also be in contact with the source/drain layer 404). In some embodiments, the layer 409 may be deposited at the bottom of the trench as well and then a portion is removed (e.g., via etching) so that the at least one contact metal layer 408 may be formed on the source/drain layer 404. The layer 409 may also be deposited in other places (e.g., on the spacers or the bottom of the trench) and then removed (e.g., via etching).

After the liner layer 409 is formed, at least one contact metal layer 408 may be deposited. In some embodiments, a first contact metal layer may first be deposited, wherein a portion of the first contact metal layer settles at the bottom of the trench and other portions of the first contact metal layer are formed on the sidewalls and top of the liner layer 409 and on the spacers 406. A second contact metal layer (e.g., comprising a cap contact metal) is then deposited on the first contact metal layer (with some of the second metal layer contacting the first metal layer along its sidewalls and some of the second metal layer contacting the first metal layer at the bottom of the trench). As shown, the height of the at least one contact metal layer 408 at the bottom of the trench is greater than the width of the at least one contact metal layer along the sidewalls of the trench. In various embodiments, any suitable deposition techniques (e.g., physical vapor deposition) may be used to form the at least one contact metal layer 408. A hardmask layer 411 may then be formed in the trench on the at least one contact metal layer 408.

At stage 400B, an etch is performed to remove the upper portion of the at least one contact metal layer 408. At stage 400C, an ashing technique is performed to remove the hardmask layer 411. At stage 400D, a sidewall etch is performed to remove the at least one contact metal layer 408 from at least a portion of the inner sidewalls of the liner layer 409.

At stage 400E, a dielectric liner layer 410 is formed on the spacers 406, top and sidewalls of liner layer 409, dielectric cap 420, and at least one contact metal layer 408. In some embodiments, the dielectric liner layer 410 may have a relatively uniform thickness.

At stage 400F, unwanted portions of the dielectric liner layer 410 are removed (e.g., through etching). For example, the portions of layer 410 over the spacers 406, dielectric caps 420, and top of liner layer 409 may be removed. A portion of the layer 410 that is on the at least one contact metal layer 408 may also be removed (e.g., using a directional etch) to expose the at least one contact metal layer 408.

At stage 400G, a fill metal layer 414 (e.g., tungsten, molybdenum, cobalt, etc.) is then deposited on the at least one contact metal layer 408 within a border defined by the dielectric liner layer 410.

In the flows above, any suitable deposition techniques may be used depending on the layer to be deposited, such as chemical vapor deposition (CVD), PVD, or atomic layer deposition (ALD). Although FIGS. 3-4 depict example stages of flows, in some implementations, the flows may include additional stages or different stages.

Although some of the embodiments depicted herein are directed towards particular types of transistors (e.g., GAA nanoribbon), the various embodiments described herein may also be utilized with other suitable transistors, such as FinFETs, planar transistors, complementary FETs (C-FETs), or other suitable transistors. In various embodiments, the transistor architectures described herein may be applied to complementary metal-oxide-semiconductor (CMOS) transistors.

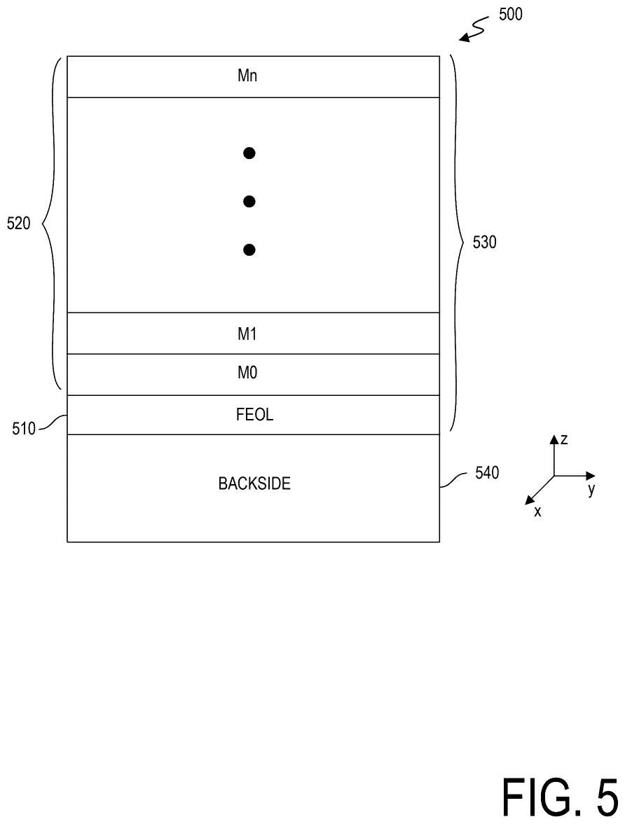

Any suitable characteristics of particular device components (e.g., contact metals, source/drain regions, gate regions, etc.) described with respect to one of the embodiments herein may also be applicable to any of the other embodiments described herein (including both the discussion above and the discussion to follow). The embodiments described in connection with FIGS. 1-4 may be adapted for inclusion within any of the architectures discussed below in connection with FIGS. 5-10.

FIG. 5 provides a schematic illustration of a cross-sectional view of an example integrated circuit device (e.g., a chip) 500. The IC device 500 may include transistors as well as other circuit elements (e.g., resistors, diodes, capacitors, inductors, etc.).

As shown in FIG. 5, the IC device 500 may include a front side 530 comprising a front-end-of-line (FEOL) 510 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL 510 may include, for example, one or more other layers or structures associated with the semiconductor devices and circuits. For example, the FEOL can also include a substrate and one or more dielectric layers that surround active and/or conductive portions of the devices and circuits. The FEOL may also include one or more conductive contacts that provide electrical contact to transistor elements such as gate structures, drain regions, or source regions. The FEOL may also include local interconnect (e.g., vias or lines) that connect contacts to interconnect features within a back-end-of-line (BEOL) 520.

The front side 530 of the IC device 500 also includes a BEOL 520 including various metal interconnect layers (e.g., metal 0 through metal n, where n is any suitable integer). Various metal layers of the BEOL 520 may be used to interconnect the various inputs and outputs of the FEOL 510.

Generally speaking, each of the metal layers of the BEOL 520, e.g., each of the layers M0-Mn shown in FIG. 5, may include a via portion and a trench/interconnect portion. Typically, the trench portion of a metal layer is above the via portion, but, in other embodiments, a trench portion may be provided below a via portion of any given metal layer of the BEOL 520. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL 520, e.g., layers M0-Mn shown in FIG. 5, may include certain patterns of conductive metals, e.g., copper (Cu) or aluminum (Al), or metal alloys, or more generally, patterns of an electrically conductive material (e.g., including carbon based materials), formed in an insulating medium such as an interlayer dielectric (ILD). The insulating medium may include any suitable ILD materials such as silicon oxide, silicon nitride, aluminum oxide, and/or silicon oxynitride. In various embodiments, any one or more of these layers may additionally include active devices (e.g., transistors, diodes) and/or passive devices (e.g., capacitors, resistors, inductors).

The IC device 500 may also include a backside 540. For example, the backside 540 may be formed on the opposite side of a wafer from the front side 530. In various embodiments, the backside 540 may include any suitable elements to assist operation of the IC device 500. For example, the backside 540 may include various metal layers to deliver power to logic of the FEOL 510.

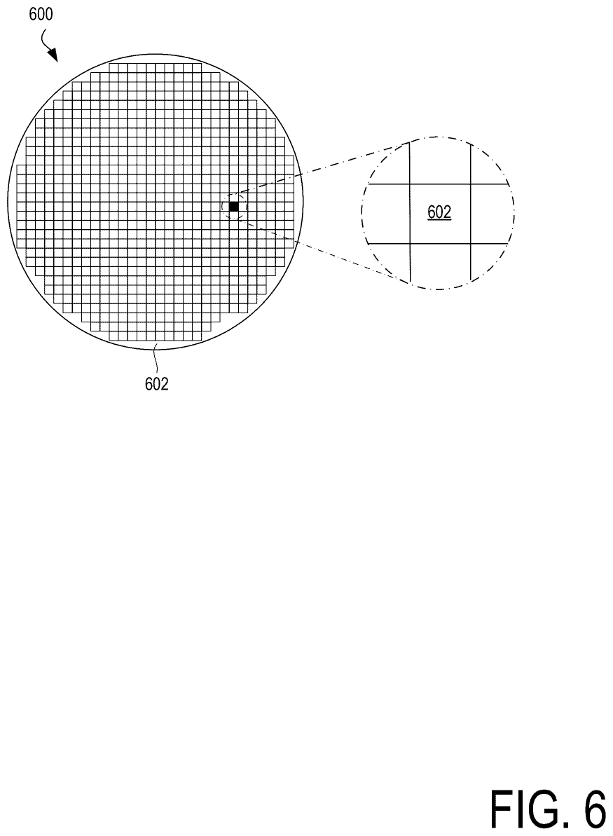

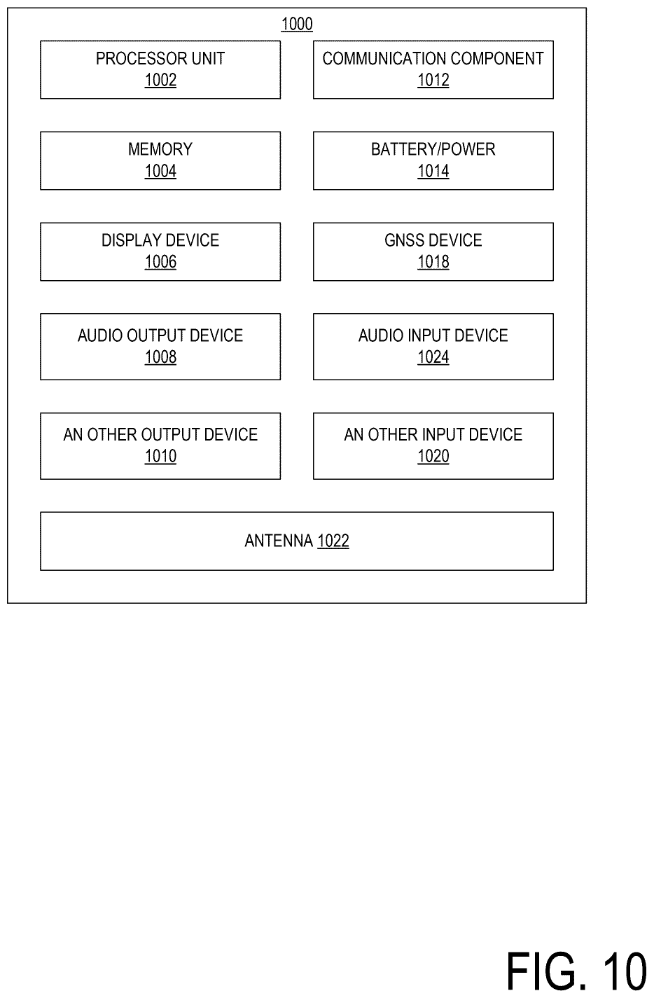

FIG. 6 is a top view of a wafer 600 and dies 602, wherein individual dies may include transistor architectures with dielectric liners on contact metal as disclosed herein. The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may include one or more transistors, supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 1002 of FIG. 10) or other logic that is configured to store information in the memory devices or execute instructions stored in the memory array. In some embodiments, various ones of the microelectronic assemblies disclosed herein may be manufactured using a die-to-wafer assembly technique in which some dies are attached to a wafer 600 that include other dies, and the wafer 600 is subsequently singulated.

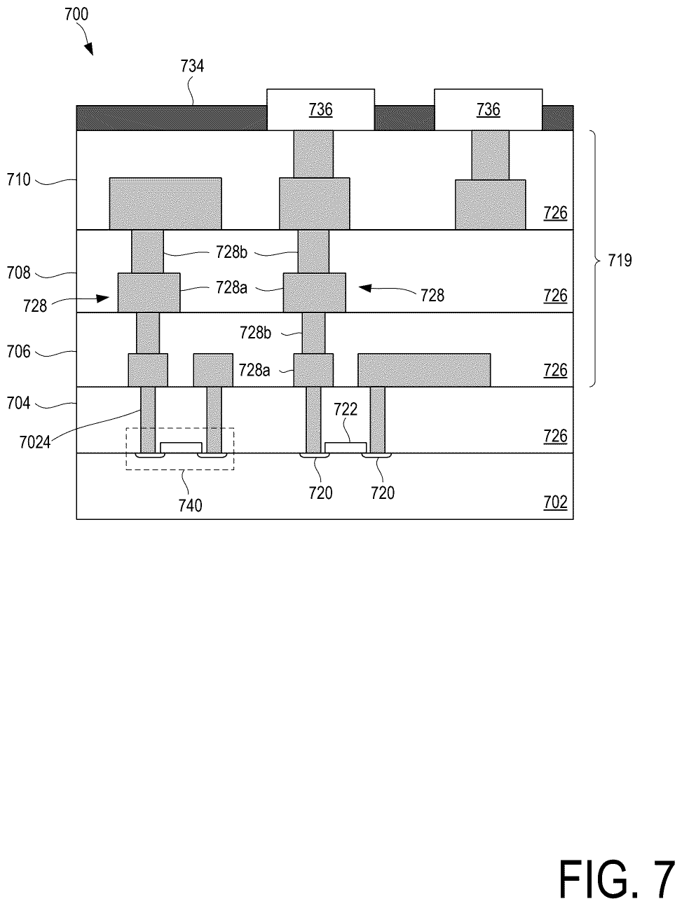

FIG. 7 is a cross-sectional side view of an integrated circuit device 700 that may include transistor architectures with dielectric liners on contact metal as disclosed herein. One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

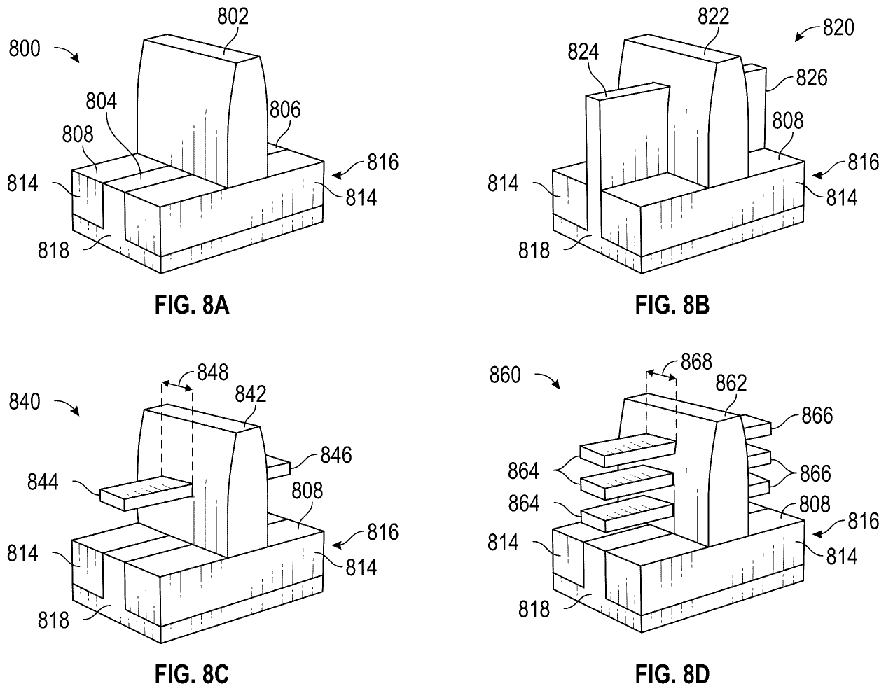

FIGS. 8A-8D are simplified perspective views of example planar, FinFET, gate-all-around, and stacked gate-all-around transistors. The transistors illustrated in FIGS. 8A-8D are formed on a substrate 816 having a surface 808. Isolation regions 814 separate the source and drain regions of the transistors from other transistors and from a bulk region 818 of the substrate 816.

FIG. 8A is a perspective view of an example planar transistor 800 comprising a gate 802 that controls current flow between a source region 804 and a drain region 806. The transistor 800 is planar in that the source region 804 and the drain region 806 are planar with respect to the substrate surface 808.

FIG. 8B is a perspective view of an example FinFET transistor 820 comprising a gate 822 that controls current flow between a source region 824 and a drain region 826. The transistor 820 is non-planar in that the source region 824 and the drain region 826 comprise “fins” that extend upwards from the substrate surface 828. As the gate 822 encompasses three sides of the semiconductor fin that extends from the source region 824 to the drain region 826, the transistor 820 can be considered a tri-gate transistor. FIG. 8B illustrates one S/D fin extending through the gate 822, but multiple S/D fins can extend through the gate of a FinFET transistor.

FIG. 8C is a perspective view of a gate-all-around (GAA) transistor 840 comprising a gate 842 that controls current flow between a source region 844 and a drain region 846. The transistor 840 is non-planar in that the source region 844 and the drain region 846 are elevated from the substrate surface 828.

FIG. 8D is a perspective view of a GAA transistor 860 comprising a gate 862 that controls current flow between multiple elevated source regions 864 and multiple elevated drain regions 866. The transistor 860 is a stacked GAA transistor as the gate controls the flow of current between multiple elevated S/D regions stacked on top of each other. The transistors 840 and 860 are considered gate-all-around transistors as the gates encompass all sides of the semiconductor portions that extends from the source regions to the drain regions. The transistors 840 and 860 can alternatively be referred to as nanowire, nanosheet, or nanoribbon transistors depending on the width (e.g., widths 848 and 868 of transistors 840 and 860, respectively) of the semiconductor portions extending through the gate.

Returning to FIG. 7, a transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of or comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of or comprise a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of or comprise a combination of U-shaped structures and planar, non-U-shaped structures. For example, the gate electrode may consist of one or more U-shaped metal layers formed atop one or more planar, non-U-shaped layers.

In some embodiments, a pair of sidewall spacers (e.g., similar to 112 described above) may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 (e.g., lines) may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. In some embodiments, TSVs extending through the substrate can be used for routing power and ground signals from conductive contacts on the opposite side of the integrated circuit device 700 from the conductive contacts 736 to the transistors 740 and any other components integrated into the integrated circuit device (e.g., die) 700, and the metallization stack 719 can be used to route I/O signals from the conductive contacts 736 to transistors 740 and any other components integrated into the integrated circuit device (e.g., die) 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

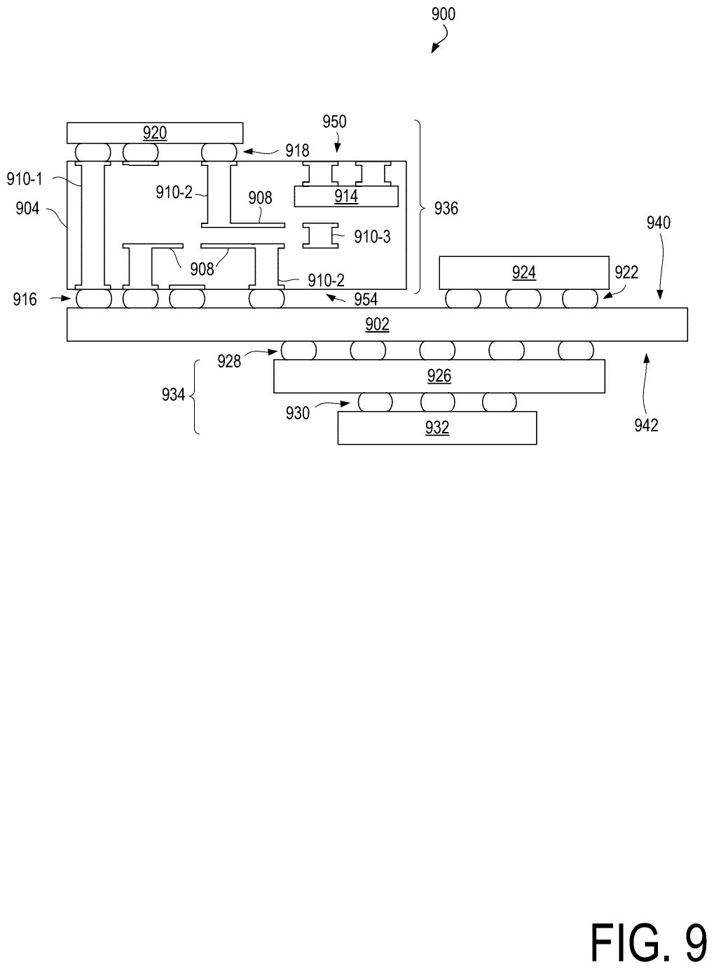

FIG. 9 is a cross-sectional side view of an integrated circuit device assembly 900 that may include transistor architectures with dielectric liners on contact metal as disclosed herein. In some embodiments, the integrated circuit device assembly 900 may be a microelectronic assembly. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpackaged integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art.

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electrical device 1000 that may include [[articulated embodiments of the present disclosure]] as disclosed herein. For example, any suitable components of the electrical device 1000 may include one or more of the integrated circuit device assemblies 900, integrated circuit components 920, integrated circuit devices 700, integrated circuit dies 602, or other components disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as amplitude modulation (AM) or frequency modulation (FM) radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include an other output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include an other input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

It will also be understood that, although the terms “first,” “second,” and so forth may be used herein to describe various elements, these elements should not be limited by these terms. These terms are only used to distinguish one element from another, and are not intended to imply that the objects so described must be in a given sequence, either temporally, spatially, in ranking or in any other manner. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. For example, the phrase “A and/or B” means (A), (B), or (A and B), while the phrase “A, B, and/or C” means (A), (B), (C), (A and B), (A and C), (B and C), or (A, B, and C).

As used throughout this description, and in the claims, a list of items joined by the term “at least one of” or “one or more of” can mean any combination of the listed terms.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, the terms “comprising,” “including,” “having,” and the like, as used with respect to embodiments of the present disclosure, are synonymous.

The description may use the phrases “in an embodiment,” “according to some embodiments,” “in accordance with embodiments,” or “in embodiments,” which may each refer to one or more of the same or different embodiments.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

The term “signal” may refer to at least one current signal, voltage signal, magnetic signal, or data/clock signal.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices.

The description may use perspective-based descriptions such as top/bottom, in/out, over/under, and the like. Such descriptions are merely used to facilitate the discussion and are not intended to restrict the application of embodiments described herein to any particular orientation.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer means that at least a part of the first material or layer is in direct physical contact with at least a part of that second material/layer. Similar distinctions are to be made in the context of component assemblies.

As used herein, “A is proximate to B” may mean that A is adjacent to B or A is otherwise near to B.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The terms “substantially,” “close,” “approximately,” “near,” and “about,” generally refer to being within +/−10% of a target value (unless specifically specified).

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an apparatus comprising a source/drain region of a transistor; a trench formed above the source/drain region; a first layer comprising metal, the first layer above the source/drain region and within the trench; a second layer comprising metal, the second layer on the first layer and within the trench; and a third layer comprising a dielectric material, wherein the third layer is within the trench, is at least partially surrounding the second layer, and is on the first layer.

Example 2 includes the subject matter of Example 1, and further including a fourth layer comprising metal, wherein the fourth layer is on the source/drain region, wherein the first layer is on the fourth layer.

Example 3 includes the subject matter of any of Examples 1 and 2, and wherein the first layer comprises a refractory metal.

Example 4 includes the subject matter of any of Examples 1-3, and wherein the first layer and the fourth layer are recessed at the bottom of the trench, such that the first layer and fourth layer are not present on at least a portion of the sidewall of the trench above the bottom of the trench.

Example 5 includes the subject matter of any of Examples 1-4, and further including a fourth layer comprising a second dielectric material, the fourth layer within the trench and at least partially surrounding the third layer.

Example 6 includes the subject matter of any of Examples 1-5, and wherein a portion of the fourth layer is between the source/drain region and the first layer.

Example 7 includes the subject matter of any of Examples 1-6, and wherein the fourth layer is thinner than the third layer.

Example 8 includes the subject matter of any of Examples 1-7, and wherein the fourth layer has a higher dielectric constant than the third layer.

Example 9 includes the subject matter of any of Examples 1-8, and wherein the fourth layer has a higher concentration of nitrogen than the third layer.

Example 10 includes the subject matter of any of Examples 1-9, and wherein the apparatus is an integrated circuit component.

Example 11 includes the subject matter of any of Examples 1-10, and wherein the apparatus further comprises a printed circuit board; and an integrated circuit component attached to the printed circuit board, the integrated circuit component comprising the transistor.

Example 12 includes the subject matter of any of Examples 1-11, and wherein the apparatus further comprises one or more additional integrated circuit components attached to the printed circuit board.

Example 13 includes an integrated circuit device comprising at least one first layer at a bottom of a trench, the at least one layer connected to a source/drain region of a transistor, the at least one layer comprising metal; a second layer on the at least one first layer, the second layer comprising metal; and a third layer on the at least one first layer and within the trench, the third layer comprising a dielectric material.

Example 14 includes the subject matter of Example 13, and further including a fourth layer within the trench, the fourth layer comprising a second dielectric material, the fourth layer between a sidewall of the trench and the third layer.

Example 15 includes the subject matter of any of Examples 13 and 14, and wherein the second dielectric material of the fourth layer has a higher dielectric constant than the dielectric material of the third layer.

Example 16 includes the subject matter of any of Examples 13-15, and wherein the at least one first layer at the bottom of the trench comprises a first metal and a second metal on the first metal, wherein the second metal is a refractory metal.

Example 17 includes the subject matter of any of Examples 13-16, and wherein a portion of the fourth layer is between the source/drain region and the at least one first layer.

Example 18 includes the subject matter of any of Examples 13-17, and wherein the at least one first layer is recessed at the bottom of the trench, such that the at least one first layer is not present on at least a portion of a sidewall of the trench above the bottom of the trench.

Example 19 includes the subject matter of any of Examples 13-18, and wherein the fourth layer is thinner than the third layer.

Example 20 includes the subject matter of any of Examples 13-19, and wherein the fourth layer has a higher concentration of nitrogen than the third layer.

Example 21 includes the subject matter of any of Examples 13-20, and further including a printed circuit board; and an integrated circuit component attached to the printed circuit board, the integrated circuit component comprising the transistor.

Example 22 includes the subject matter of any of Examples 13-21, and further including one or more additional integrated circuit components attached to the printed circuit board.

Example 23 includes a method comprising forming a trench to a source/drain region of a field effect transistor; forming at least one first layer at the bottom of the trench, the at least one first layer comprising metal; forming a second layer within the trench on top of the at least one first layer, the second layer comprising a dielectric material; and forming a third layer within the trench on top of the at least one first layer, the third layer comprising metal.

Example 24 includes the subject matter of Example 23, and further including forming a fourth layer within the trench on a sidewall of the trench, the fourth layer contacting the second layer, the fourth layer comprising a second dielectric material.

Example 25 includes the subject matter of any of Examples 23 and 24, and wherein the second dielectric material of the fourth layer has a higher dielectric constant than the dielectric material of the second layer.

Example 26 includes the subject matter of any of Examples 23-25, and wherein forming the at least one first layer comprises forming a first metal and capping the first metal with a refractory metal.

Example 27 includes the subject matter of any of Examples 23-26, and wherein a portion of the fourth layer is between the source/drain region and the at least one first layer.

Example 28 includes the subject matter of any of Examples 23-27, and wherein the at least one first layer is recessed at the bottom of the trench, such that the at least one first layer is not present on at least a portion of a sidewall of the trench above the bottom of the trench.

Example 29 includes the subject matter of any of Examples 23-28, and wherein the fourth layer is thinner than the third layer.

Example 30 includes the subject matter of any of Examples 23-29, and wherein the fourth layer has a higher concentration of nitrogen than the third layer.

Example 31 includes the subject matter of any of Examples 23-30, and further including attaching an integrated circuit component comprising the transistor to a printed circuit board.

Example 32 includes the subject matter of any of Examples 23-31, and further including attaching one or more additional integrated circuit components to the printed circuit board.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. An apparatus comprising:
a source/drain region of a transistor;
a trench formed above the source/drain region;
a first layer comprising metal, the first layer above the source/drain region and within the trench;
a second layer comprising metal, the second layer on the first layer and within the trench; and
a third layer comprising a dielectric material, wherein the third layer is within the trench, is in contact with the second layer, and is on the first layer.

2. The apparatus of claim 1, further comprising a fourth layer comprising metal, wherein the fourth layer is on the source/drain region, wherein the first layer is on the fourth layer.

3. The apparatus of claim 2, wherein the first layer comprises a refractory metal.

4. The apparatus of claim 2, wherein the first layer and the fourth layer are recessed at a bottom of the trench, such that the first layer and fourth layer are not present on at least a portion of a sidewall of the trench above the bottom of the trench.

5. The apparatus of claim 1, further comprising a fourth layer comprising a second dielectric material, the fourth layer within the trench and in contact with the third layer.

6. The apparatus of claim 5, wherein a portion of the fourth layer is between the source/drain region and the first layer.

7. The apparatus of claim 5, wherein the fourth layer is thinner than the third layer.

8. The apparatus of claim 5, wherein the fourth layer has a higher dielectric constant than the third layer.

9. The apparatus of claim 5, wherein the fourth layer has a higher concentration of nitrogen than the third layer.

10. The apparatus of claim 1, wherein the apparatus is an integrated circuit component.

11. The apparatus of claim 1, wherein the apparatus further comprises:
a printed circuit board; and
an integrated circuit component attached to the printed circuit board, the integrated circuit component comprising the transistor.

12. The apparatus of claim 11, wherein the apparatus further comprises one or more additional integrated circuit components attached to the printed circuit board.

13. An integrated circuit device comprising:
at least one first layer at a bottom of a trench, the at least one first layer connected to a source/drain region of a transistor, the at least one first layer comprising metal;
a second layer on the at least one first layer, the second layer comprising metal; and
a third layer on the at least one first layer and within the trench, the third layer comprising a dielectric material.

14. The integrated circuit device of claim 13, further comprising a fourth layer within the trench, the fourth layer comprising a second dielectric material, the fourth layer between a sidewall of the trench and the third layer.

15. The integrated circuit device of claim 14, wherein the second dielectric material of the fourth layer has a higher dielectric constant than the dielectric material of the third layer.

16. The integrated circuit device of claim 13, wherein the at least one first layer at the bottom of the trench comprises a first metal and a second metal on the first metal, wherein the second metal is a refractory metal.

17. A method comprising:
forming a trench to a source/drain region of a field effect transistor;
forming at least one first layer at a bottom of the trench, the at least one first layer comprising metal;
forming a second layer within the trench on top of the at least one first layer, the second layer comprising a dielectric material; and
forming a third layer within the trench on top of the at least one first layer, the third layer comprising metal.

18. The method of claim 17, further comprising forming a fourth layer within the trench on a sidewall of the trench, the fourth layer contacting the second layer, the fourth layer comprising a second dielectric material.

19. The method of claim 18, wherein the second dielectric material of the fourth layer has a higher dielectric constant than the dielectric material of the second layer.

20. The method of claim 17, wherein forming the at least one first layer comprises forming a first metal and capping the first metal with a refractory metal.
